(19) United States
(12) Patent Application Publication
(10) Pub. No.: US 2020/0076396 A1
(43) Pub. Date: Mar. 5, 2020

(54) MATCHING NETWORK CIRCUIT AND TUNING METHOD THEREOF

(71) Applicant: MediaTek Singapore Pte. Ltd., Singapore (SG)

(72) Inventors: Liming JIN, Singapore (SG); Wei YANG, Singapore (SG)

(21) Appl. No.: 16/419,079

(22) Filed: May 22, 2019

Related U.S. Application Data
(60) Provisional application No. 62/724,103, filed on Aug. 29, 2018.

(51) Int. Cl. H03H 7/40

(52) U.S. Cl. CPC H03H 7/40

(57) ABSTRACT

A matching network circuit with tunable impedance and a tuning method thereof provided. The matching network circuit includes an inductor, a tunable capacitor, a tunable resistor and an auto-tuning circuit. The tunable capacitor is connected to the inductor. The tunable resistor is connected to the inductor. The auto-tuning circuit is connected to the tunable capacitor and the tunable resistor. Auto-turning circuit tunes the tunable capacitor and the tunable resistor over process variation.

This application claims the benefit of U.S. provisional application Ser. No. 62/724,103, filed Aug. 29, 2018, the disclosure of which is incorporated by reference herein in its entirety.

### TECHNICAL FIELD

The disclosure relates in general to a matching network circuit and a tuning method thereof, and more particularly to a matching network circuit with tunable impedance and a tuning method.

### BACKGROUND

Along with the development of the wireless transmission technology, several communication devices are invented. In the communication device, a matching network circuit between a Radio-Frequency (RF) front-end module and a receiver chip is necessary. In conventional, a matching network circuit with an inductor and a shunt capacitor connected in series is widely used. However, this conventional matching network circuit has a limited bandwidth and is not suitable for wideband application. Therefore, the researchers try to design a novel matching network circuit having wide bandwidth.

### SUMMARY

The disclosure is directed to a matching network circuit and a tuning method thereof. The matching network circuit includes a tunable capacitor and a tunable resistor; therefore, the resonant frequency can cover wide range and the input matching can be optimized over wide frequency range. Moreover, a calibration over process can help to overcome the process variation of the on-chip capacitor and the on-chip resistor.

According to one embodiment, a matching network circuit with tunable impedance is provided. The matching network circuit includes an inductor, a tunable capacitor, a tunable resistor and an auto-tuning circuit. The tunable capacitor is connected to the inductor. The tunable resistor is connected to the inductor. The auto-tuning circuit is connected to the tunable capacitor and the tunable resistor. The auto-turning circuit tunes the tunable capacitor and the tunable resistor over an interested frequency.

According to another embodiment, a tuning method of a matching network circuit is provided. The matching network circuit includes an inductor, a tunable capacitor, a tunable resistor and an auto-tuning circuit. The tunable capacitor is connected to the inductor. The tunable resistor is connected to the inductor. The auto-tuning circuit is connected to the tunable capacitor and the tunable resistor. The tuning method includes the following steps. The tunable capacitor is tuned over an interested frequency. The tunable resistor is tuned over the interested frequency.

### BRIEF DESCRIPTION OF THE DRAWINGS

FIG. 1 shows a matching network circuit with tunable impedance according to one embodiment.

FIG. 2 shows a tunable capacitor according to one embodiment.

FIG. 3 shows a tunable resistor according to one embodiment.

FIG. 4 shows three S11 curves of the matching network circuit without calibration.

FIG. 5 shows a flowchart of a calibration method according to one embodiment.

FIG. 6 shows a flowchart of a calibration method according to another embodiment.

FIG. 7 shows a tuning method of the matching network circuit according to one embodiment.

FIG. 8 shows three S11 curves of a matching network circuit without the tunable capacitor and the tunable resistor.

FIG. 9 shows three S11 curves of the matching network circuit with the tunable capacitor and the tunable resistor.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

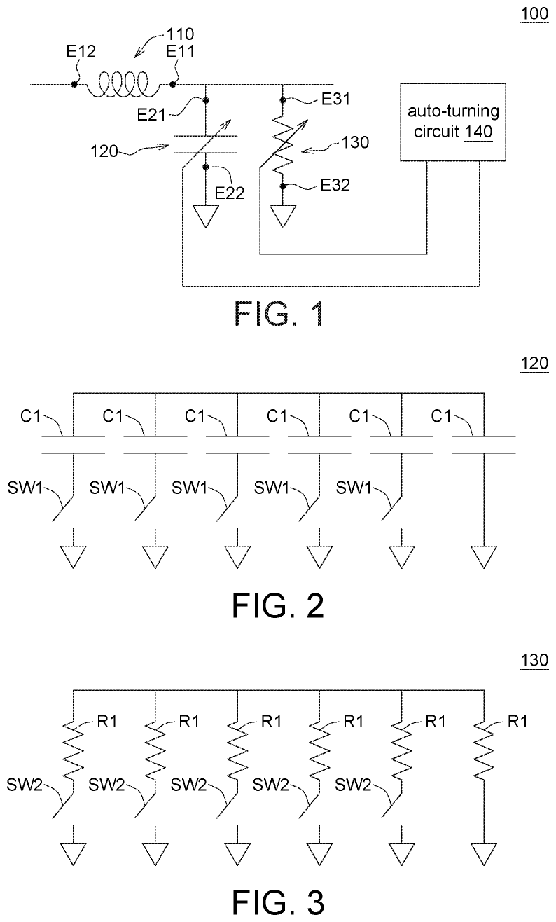

Please referring to FIG. 1, a matching network circuit 100 with tunable impedance according to one embodiment is shown. The matching network circuit 100 includes an inductor 110, a tunable capacitor 120, a tunable resistor 130 and an auto-turning circuit 140. The inductor 110 has a first end E11 and a second E12. The tunable capacitor 120 may be a tunable shunt capacitor. The tunable capacitor 120 has a first end E21 and a second end E22. The first end E21 of the tunable capacitor 120 is connected to the first end E11 of the inductor 110. The tunable resistor 130 may be a tunable shunt resistor. The tunable resistor 130 has a first end E31 and a second end E32. The first end E31 of the tunable resistor 130 is connected to the first end E11 of the inductor 110. The tunable capacitor 120 and the tunable resistor 130 are connected in parallel. The auto-turning circuit 140 is connected to the second end E22 of the tunable capacitor 120 and the second end E32 of the tunable resistor 130.

The auto-turning circuit 140 is used to tune the tunable capacitor 120, such that the resonant frequency of the matching network circuit 100 can cover wide range.

The auto-turning circuit 140 is also used to tune the tunable resistor 130 over an interested frequency, such that the input matching can be optimized over wide frequency range.

Please refer to FIG. 2, which shows the tunable capacitor 120 according to one embodiment. In one embodiment, the tunable capacitor 120 may be a digital controlled capacitor array. A plurality of capacitors C1 are connected in parallel. The auto-turning circuit 140 controls a plurality of switches SW1 to be connected or disconnected, such that the capacitance of the tunable capacitor 120 is controlled.

Please refer to FIG. 3, which shows the tunable resistor 130 according to one embodiment. In one embodiment, the tunable resistor 130 may be a digital controlled resistor array. A plurality of resistors R1 are connected in parallel. The auto-turning circuit 140 controls a plurality of switches SW2 to be connected or disconnected, such that the resistance of the tunable resistor 130 is controlled.

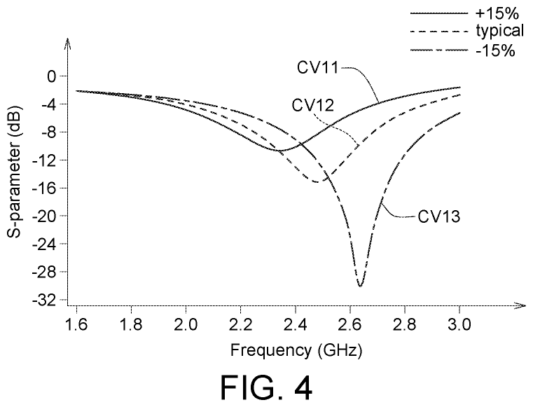

Moreover, in one embodiment, the tunable capacitor 120 and the tunable resistor 130 are an on-chip capacitor and an on-chip resistor which have large process variation and may cause impedance deviation from target. Please refer to FIG. 4, which shows three S11 curves CV11, CV12, CV13 of the matching network circuit 100 without calibration. A S11 curve represents how much power is reflected from the antenna, and hence is known as the reflection coefficient (sometimes written as gamma: Γ, return loss, or S-parameter). The S11 curve would typically be measured using a Vector Network Analyzer (VNA). The bandwidth can also be determined from the S11 curve.

The tunable capacitor 120 and the tunable resistor 130 are the on-chip capacitor and the on-chip resistor which have large process variation. In one embodiment, the tunable capacitor 120 may have +15% C-corner, the tunable resistor 130 may have +15% R-corner, and the S11 curve CV11 thereof is shown in FIG. 4. In another embodiment, the tunable capacitor 120 may have typical C-corner, the tunable resistor 130 may have typical R-corner, and the S11 curve thereof is like the S11 curve CV12 thereof is shown in FIG. 4. In another embodiment, the tunable capacitor 120 may have −15% C-corner, the tunable resistor 130 may have −15% R-corner, and the S11 curve CV13 thereof is shown in FIG. 4. The S11 curves CV11, CV12, CV13 are varied with the process variation, so a calibration is needed to overcome this variation.

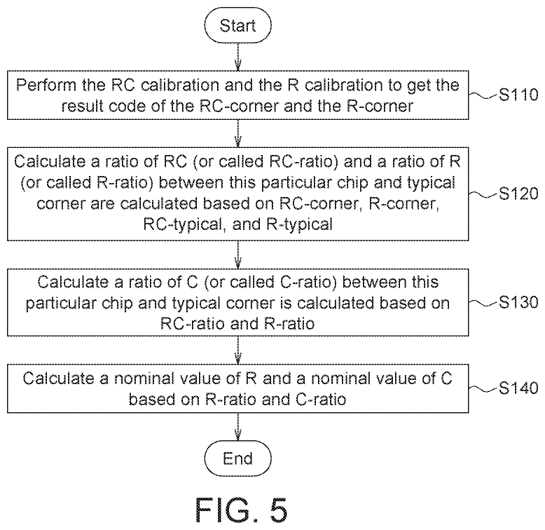

Please refer to FIG. 5, which shows a flowchart of a calibration method according to one embodiment. In one embodiment, a RC calibration and a R calibration under a typical RC-corner and a typical R-corner may be performed in design phase. For a particular chip, the result of RC-typical and the R-typical is stored. In step S110, the RC calibration and the R calibration are performed to get the result code of the RC-corner and the R-corner.

In step S120, a ratio of RC (or called RC-ratio) and a ratio of R (or called R-ratio) between this particular chip and typical corner are calculated based on RC-corner, R-corner, RC-typical, and R-typical. That is to say, RC-ratio equals to

$$\frac{RC \text{-} corner}{RC \text{-} typical} ,$$

and R-ratio equals to

$$\frac{R \text{-} corner}{R \text{-} typical} .$$

In step S130, a ratio of C (or called C-ratio) between this particular chip and typical corner is calculated based on RC-ratio and R-ratio. That is to say, C-ratio equals to

$$\frac{RC \text{-} ratio}{R \text{-} ratio} .$$

In step S140, a nominal value of R and a nominal value of C are calculated based on R-ratio and C-ratio. The nominal value of R equals to

$$\frac{R \text{-} typical}{R \text{-} ratio} ,$$

and the nominal value of C equals to

$$\frac{C \text{-} typical}{C \text{-} ratio} .$$

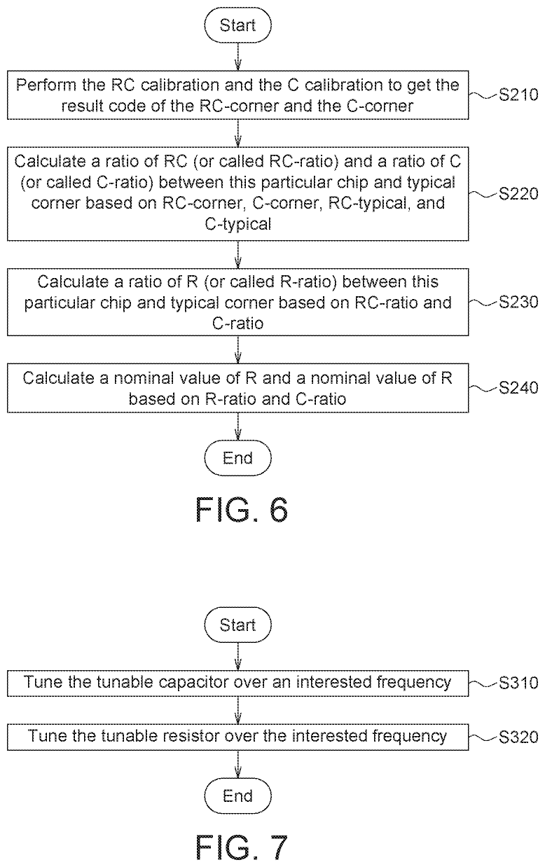

Please refer to FIG. 6, which shows a flowchart of a calibration method according to another embodiment. In one embodiment, a RC calibration and a C calibration under typical corner may be performed in design phase. For a particular chip, the result of RC-typical and the C-typical is stored. In step S210, the RC calibration and the C calibration are performed to get the result code of the RC-corner and the C-corner.

In step S220, a ratio of RC (or called RC-ratio) and a ratio of C (or called C-ratio) between this particular chip and typical corner are calculated based on RC-corner, C-corner, RC-typical, and C-typical. That is to say, RC-ratio equals to

$$\frac{RC \text{-} corner}{RC \text{-} typical} ,$$

and u-ratio equals to

$$\frac{C \text{-} corner}{C \text{-} typical} .$$

In step S230, a ratio of R (or called R-ratio) between this particular chip and typical corner is calculated based on RC-ratio and C-ratio. That is to say, R-ratio equals to

$$\frac{RC \text{-} ratio}{C \text{-} ratio} .$$

In step S240, a nominal value of R and a nominal value of R are calculated based on R-ratio and C-ratio. The nominal value of R equals to

$$\frac{R \text{-} typical}{R \text{-} ratio} ,$$

and the nominal value of C equals to

$$\frac{C \text{-} typical}{C \text{-} ratio} .$$

After calibration, the performance of the matching network circuit 100 is stable. Then, the matching network circuit 100 can be turned by the following tuning method, such that the resonant frequency of the matching network circuit 100 can cover wide range.

Please refer to FIG. 7, which shows a tuning method of the matching network circuit 100 according to one embodiment. In step S310, the tunable capacitor 120 is tuned over an interested frequency. In step S320, the tunable resistor 130 is tuned over the interested frequency. Refer to the following equation (1).

$${Z}_{in} = \frac{R}{1 + {ω}^{2} {C}^{2} {R}^{2}} + j ( ω L - \frac{ω {R}^{2} C}{1 + {ω}^{2} {C}^{2} {R}^{2}} ) \qquad ( 1 )$$

Zᵢₙ is an input impedance of the matching network circuit 100, C is a capacitance of the tunable capacitor 120, R is a resistance of the tunable resistor 130, and L is an inductance of the inductor 110.

As

$$RC >> \frac{1}{ω} ,$$

the equation (1) can be written as the following equation (2).

$${Z}_{in} \approx \frac{R}{{ω}^{2} {C}^{2} {R}^{2}} + j ( ω L - \frac{ω {R}^{2} C}{{ω}^{2} {C}^{2} {R}^{2}} ) = \frac{1}{{ω}^{2} {C}^{2} R} + j ( ω L - \frac{1}{ω C} ) \qquad ( 2 )$$

To achieve the input matching, let

$$ω L - \frac{1}{ω C} = 0 ,$$

then

$${Z}_{in} = \frac{L}{CR} .$$

In the step S310, the capacitance of the tunable capacitor 120 is tuned to make an imaginary part

$$( “ ω L - \frac{1}{ω C} ” )$$

of the matching network circuit 100 to 0. That is to say,

$$C = \frac{1}{{ω}^{2} L} .$$

In the step S320, the resistance of the tunable resistor 130 is tuned to make a real part

$$( “ \frac{1}{{ω}^{2} {C}^{2} R} ” )$$

of the input impedance of the matching network circuit 100 to 50Ω.

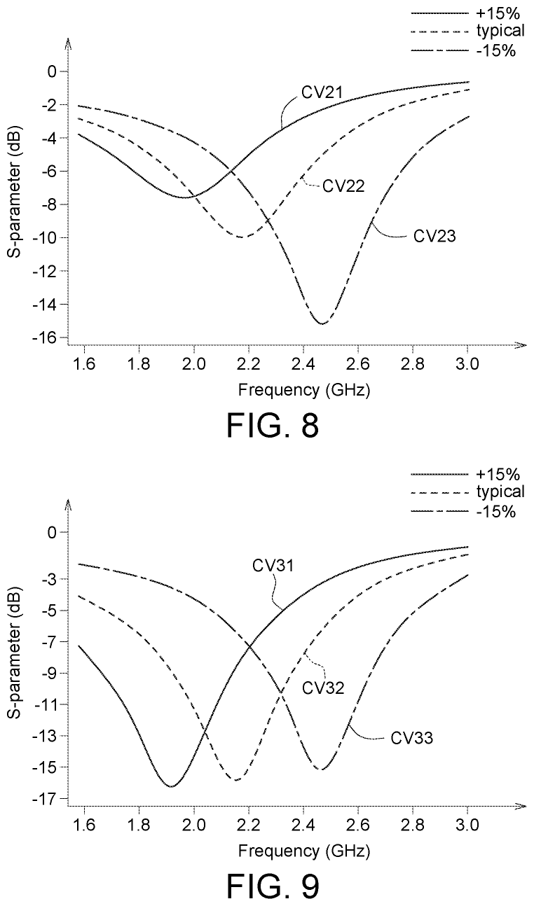

Please refer to FIGS. 8 and 9. FIG. 8 shows three S11 curves CV21, CV22, CV23 of a matching network circuit (not shown) without the tunable resistor 130, and FIG. 9 shows three S11 curves CV31, CV32, CV33 of the matching network circuit 100 with the tunable capacitor 120 and the tunable resistor 130. Comparing with the FIG. 8 and FIG. 9, the tunable capacitor 120 is tuned to make the LC resonate at the frequency of interest and the tunable resistor 130 is tuned to keep the S11 curves CV31, CV32, CV33 stable at resonant frequency while the tunable capacitor 120 is tuned.

According to the embodiments described above, the matching network circuit 100 includes the tunable capacitor 120, therefore the resonant frequency can cover wide range. Further, the tunable resistor 130 is adjusted according to the real part of input impedance, so that the input matching can be optimized over wide frequency range. Moreover, the calibration over process can help to overcome the process variation of the on-chip capacitor and the on-chip resistor.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A matching network circuit with tunable impedance; comprising:
an inductor;
a tunable capacitor, connected to the inductor;
a tunable resistor, connected to the inductor; and
an auto-tuning circuit, connected to the tunable capacitor and the tunable resistor, wherein the auto-turning circuit tunes the tunable capacitor and the tunable resistor over an interested frequency.

2. The matching network circuit according to claim 1, wherein the tunable capacitor and the tunable resistor are connected at an identical end of the inductor.

3. The matching network circuit according to claim 1, wherein the tunable capacitor is an on-chip capacitor and the tunable resistor is an on-chip resistor.

4. The matching network circuit according to claim 1, wherein a capacitance of the tunable capacitor is tuned to make an imaginary part of an input impedance of the matching network circuit to 0.

5. The matching network circuit according to claim 1, wherein a resistance of the tunable resistor is tuned to make a real part of an input impedance of the matching network circuit to 50.

6. The matching network circuit according to claim 1, wherein the tunable resistor and the tunable capacitor are calibrated by a RC calibration and a R calibration.

7. The matching network circuit according to claim 1, wherein the tunable resistor and the tunable capacitor are calibrated by a RC calibration and a C calibration.

8. The matching network circuit according to claim 1, wherein the tunable resistor is a resistor array.

9. The matching network circuit according to claim 8, wherein the resistor array includes a plurality of resistors and a plurality of switches, and each of the switches is connected to one of the resistors.

10. The matching network circuit according to claim 1, wherein the tunable capacitor is a capacitor array.

11. The matching network circuit according to claim 10, wherein the capacitor array includes a plurality of capacitors and a plurality of switches, and each of the switches is connected to one of the capacitors.

12. A tuning method of a matching network circuit, wherein the matching network circuit includes an inductor, a tunable capacitor, a tunable resistor and auto-tuning circuit, the tunable capacitor is connected to the inductor, the tunable resistor is connected to the inductor, the auto-tuning circuit is connected to the tunable capacitor and the tunable resistor, and the tuning method comprises:
tuning the tunable capacitor over an interested frequency; and
tuning the tunable resistor over the interested frequency.

13. The tuning method according to claim 12, wherein the tunable capacitor and the tunable resistor are connected at an identical end of the inductor.

14. The tuning method according to claim 12, wherein the tunable capacitor is an on-chip capacitor and the tunable resistor is an on-chip resistor.

15. The tuning method according to claim 12, wherein in the step of tuning the tunable capacitor, a capacitance of the tunable capacitor is tuned to make an imaginary part of an input impedance of the matching network circuit to 0.

16. The tuning method according to claim 12, wherein in the step of tuning the tunable resistor, a resistance of the tunable resistor is tuned to make a real part of an input impedance of the matching network circuit to 50.

17. The tuning method according to claim 12, wherein the tunable resistor and the tunable capacitor are calibrated by a RC calibration and a R calibration.

18. The tuning method according to claim 12, wherein the tunable resistor and the tunable capacitor are calibrated by a RC calibration and a C calibration.

19. The tuning method according to claim 12, wherein the tunable resistor is a resistor array.

20. The tuning method according to claim 19, wherein the capacitor array includes a plurality of capacitors and a plurality of switches, and each of the switches is connected to one of the capacitors.

21. The tuning method according to claim 12, wherein the tunable capacitor is a capacitor array.

22. The tuning method according to claim 21, wherein the capacitor array includes a plurality of capacitors and a plurality of switches, and each of the switches is connected to one of the capacitors.
